(19) United States
(12) Patent Application Publication
(10) Pub. No.: US 2014/0198459 A1
(43) Pub. Date: Jul. 17, 2014

(54) STACKED PACKAGE DEVICE AND MANUFACTURING METHOD THEREOF

(71) Applicant: ADVANCED SEMICONDUCTOR ENGINEERING INC., Kaohsiung City (TW)

(72) Inventor: TSUNG-JUNG CHENG, NANTOU COUNTY (TW)

(73) Assignee: Advanced Semiconductor Engineering Inc., Kaohsiung city 811 (TW)

(21) Appl. No.: 13/867,285

(22) Filed: Apr. 22, 2013

(30) Foreign Application Priority Data
Jan. 11, 2013 (TW) 102101125

(51) Int. Cl. H01L 23/552; H01L 21/56

(52) U.S. Cl. CPC H01L 23/552; H01L 21/565
USPC 361/730; 257/659; 438/109

(57) ABSTRACT

A stacked package device includes a substrate, at least one electronic component and a molding unit. The molding unit includes a first insulation layer, a second insulation layer, and a first shielding layer. The electronic component is disposed on the substrate. The first insulation layer is disposed on the substrate and covers the electronic component. The first insulation layer has a plurality of holes, and is disposed on the first insulation layer. The second insulation layer is disposed on the first shielding layer. The first insulation layer is connected to the second insulation layer through the holes.

### BACKGROUND

1. Technical Field

The present disclosure relates to a stacked package device; in particular, a stacked package device which includes electromagnetic shielding layer.

2. Description of Related Art

Recently, the stacked package module is usually multilayered package structure on the substrate, namely packaging various electronic components and designing different electrical connection according to processing requirement. To increase the stacking density of semiconductor components and decrease the package volume, the semiconductor components would be stacked through 3D vertically integrated circuits.

Generally speaking, the stacked package module includes a plurality of electronic components. While the electronic module which has stacked package module is operating, the electronic components would generate electromagnetic waves. To decrease the electromagnetic interference and radio frequency interference of the electronic component, an electromagnetic shielding layer would be used in the stacked package module.

Because the material of the electromagnetic shielding layer is different from the material of molding compound, the delamination is likely to occur, so the yield rate may decrease.

### SUMMARY

An exemplary embodiment of the present disclosure illustrates a stacked package device. The stacked package device includes a first shielding layer, which is formed with holes. The holes allow the first and second insulation layer materials for bonding homogeneously.

An exemplary embodiment of the present disclosure illustrates a stacked package device. The stacked package device includes a substrate, at least one electronic component and a molding unit. The molding unit includes a first insulation layer, a second insulation layer, and a first shielding layer. The electronic component is disposed on the substrate. The first insulation layer is disposed on the substrate and covers the electronic components. The first shielding layer has a plurality of holes. The first shielding layer is disposed on the first insulation layer. The second insulation layer is disposed on the first shielding layer. The first insulation layer is connected to the second insulation layer through the holes.

An exemplary embodiment of the present disclosure illustrates a method of manufacturing stacked package device. The method of manufacturing stacked package device is used to improve the conventional method of stacked package device. The method of manufacturing the stacked package device includes the following steps. At least one electronic component is disposed on a substrate, and the electronic component is electrically connected to the substrate. The first insulation layer is formed on the substrate, and the first insulation layer covers the electronic component. A metal layer is formed on the first insulation layer. The metal layer is patterned so that a first shielding layer is formed. The first shielding layer is formed with a plurality of holes.

In addition, an exemplary embodiment of the present disclosure illustrates an electronic device. The electronic device includes a console and at least one stacked package device. The console includes a case, at least one electronic module and a circuit board. The at least one electronic module and the circuit board are disposed in the case. The substrate of the stacked package device is electrically connected to the circuit board.

To sum up, the present disclosure illustrates a stacked package device including the first shielding layer. The first shielding layer has a plurality of holes, and the holes allow the first and second insulation layer bonding homogeneously. The first insulation layer may be in contact with the second insulation layer through the holes. Hence, the first insulation layer and the second insulation layer may closely combine with each other. Therefore, the delamination between the first insulation layer, the second insulation layer, and the first shielding layer may be avoided.

In order to further understand the techniques, means and effects of the present disclosure, the following detailed descriptions and appended drawings are hereby referred, such that, through which, the purposes, features and aspects of the present disclosure can be thoroughly and concretely appreciated; however, the appended drawings are merely provided for reference and illustration, without any intention to be used for limiting the present disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1A depicts a top view diagram of a stacked package device in accordance with an exemplary embodiment of the present disclosure.

FIG. 1B depicts a cross-sectional view of a stacked package device shown in FIG. 1A along a line P-P in accordance with an exemplary embodiment of the present disclosure.

FIG. 2A to 2E depict a semi-finished article diagram of a stacked package device in each step in accordance with an exemplary embodiment of the present disclosure.

FIG. 3 depicts a cross-sectional view of an electronic device in accordance with an exemplary embodiment of the present disclosure.

### DESCRIPTION OF THE EXEMPLARY EMBODIMENTS

Reference will now be made in detail to the exemplary embodiments of the present disclosure, examples of which are illustrated in the accompanying drawings. Wherever possible, the same reference numbers are used in the drawings and the description to refer to the same or like parts.

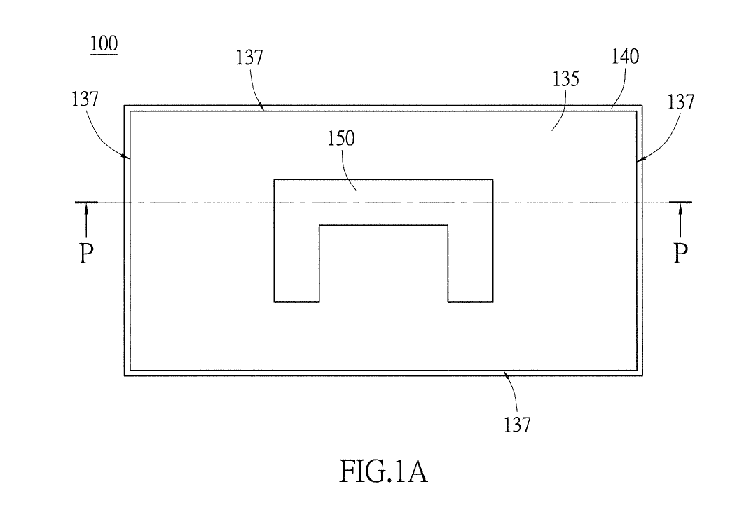

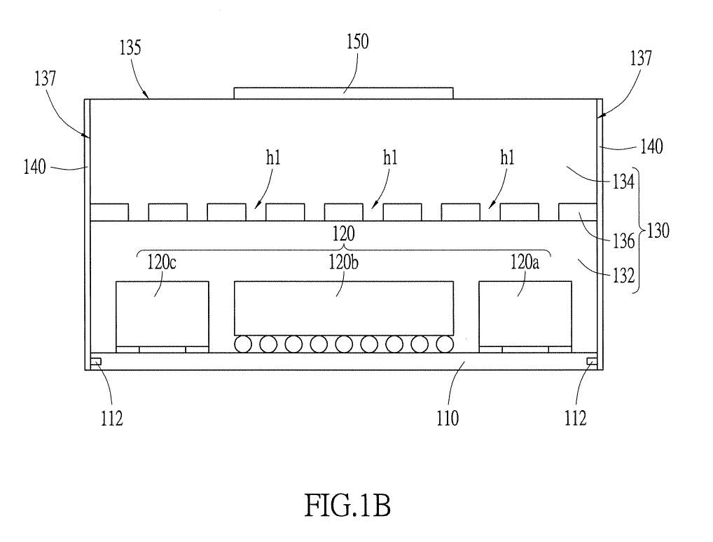

FIG. 1A illustrates a top view of a stacked package device in accordance to an exemplary embodiment of the present disclosure. FIG. 1B illustrates a cross-sectional view of a stacked package device shown in FIG. 1A along a line P-P in accordance with an exemplary embodiment of the present disclosure. Please refer to FIGS. 1A and 1B. The stacked package device 100 includes a substrate 110, at least one electronic component 120 and a molding unit 130. The electronic component 120 is disposed on the substrate 110. The molding unit 130 is disposed on the electronic component 120. The molding unit 130 is connected to the substrate 110.

The electronic component 120 is disposed on the substrate 110. The electronic component 120 is electrically connected to the substrate 110 to transmit electric signal. The substrate 110 is used to be a carrier for circuit and electronic component. Pads and trace are disposed on the substrate 110. In practical, the pads and traces may be disposed according to the arrangement of the electronic component 120. The electronic component 120 may be electrically connected to the substrate 110 by many ways. For example, the electronic component 120 may be electrically connected to the pads and traces of the substrate 110 by wire bonding, flip chip bonding or other package methods.

Additionally, in the instant embodiment, the electronic components 120 may vary. Namely, the types of the electronic components 120 are different, such as chips, transistors, diodes, capacitances, inductances, etc. Please refer to FIG. 1B. The electronic components 120 are shown as the electronic components 120a, 120b, and 120c. The present disclosure is not limited to the types of the electronic component 120.

The substrate 110 can be a chip carrier substrate, silicon substrate or the substrate composed of Epoxy resin, Cyanate ester core or Bismaleimide core, etc.

The molding unit 130 has a top surface 135 and a plurality of sidewalls 137. The sidewalls 137 are coupled to the top surface 135. And the sidewalls 137 surround the top surface 135. In the instant embodiment, the number of the sidewalls 137 is four. The present disclosure is not limited to the number of the sidewalls 137.

The molding unit 130 includes a first insulation layer 132, a second insulation layer 134, and a first shielding layer 136. The first insulation layer 132 is disposed on the substrate 110 and covers the electronic components 120. The upper surface of first insulation layer 132 is flat. The first shielding layer 136 is disposed on the upper surface of the first insulation layer 132, and does not extend to the lateral side of the first insulation layer 132. The second insulation layer 134 is disposed on the first shielding layer 136.

The first insulation layer 132 and the second insulation layer 134 are molding layers. The first insulation layer 132 and the second insulation layer 134 are used to prevent the electronic components 120 from electrically coupling to each other or having short-circuited. The first insulation layer 132 and the second insulation layer 134 may be made of epoxy resin or silica gel.

The first shielding layer 136 covers the upper surface of the first insulation layer 132. The first shielding layer 136 serves as an electromagnetic shielding layer and decreases the electromagnetic interference (EMI) and radio frequency interference (RFI) of the electronic component 120. The first shielding layer 136 has a plurality of holes h1. A portion of the first insulation layer 132 may be exposed through the holes h1. For increasing the electromagnetic interference shielding effectiveness, the shielding ambit and shielding position of the first shielding layer 136 may be designed in various ways according to intended purpose. The shape, number and distribution of the holes h1 may be designed according to electromagnetic interference shielding requirement.

As mentioned above, the first shielding layer 136 is disposed between the first insulation layer 132 and the second insulation layer 134. The first insulation layer 132 may be in contact with the second insulation layer 134 through the holes h1. The first insulation layer material and the second insulation layer material may be the same, so that the first insulation layer 132 and the second insulation layer 134 may form homogeneous connection, i.e. tight bonds there-between, through the holes h1. Hence, the first insulation layer 132 and the second insulation layer 134 may closely combine with each other, and the bonding strength of the molding compound between different layer is enhanced. Therefore, the delamination between the first insulation layer 132, the second insulation layer 134, and the first shielding layer 136 may be avoided.

The stacked package device 100 may further include a second shielding layer 140. The second shielding layer 140 is disposed on portion of exterior of the molding unit 130, for example, at least one sidewall 137. The second shielding layer 140 is electrically connected to the first shielding layer 136. The second shielding layer 140 may be used as a grounding electromagnetic interference shielding layer to transmit the signal of the first shielding layer 136 to the grounding pad 112 of the substrate 110. The second shielding layer 140 may also decrease the electromagnetic interference and radio frequency interference of the electronic component 120.

In the instant embodiment, the material of the first shielding layer 136 and the second shielding layer 140 are metal material, for example, cooper, silver, nickel, composition metal material, conducting polymer, etc.

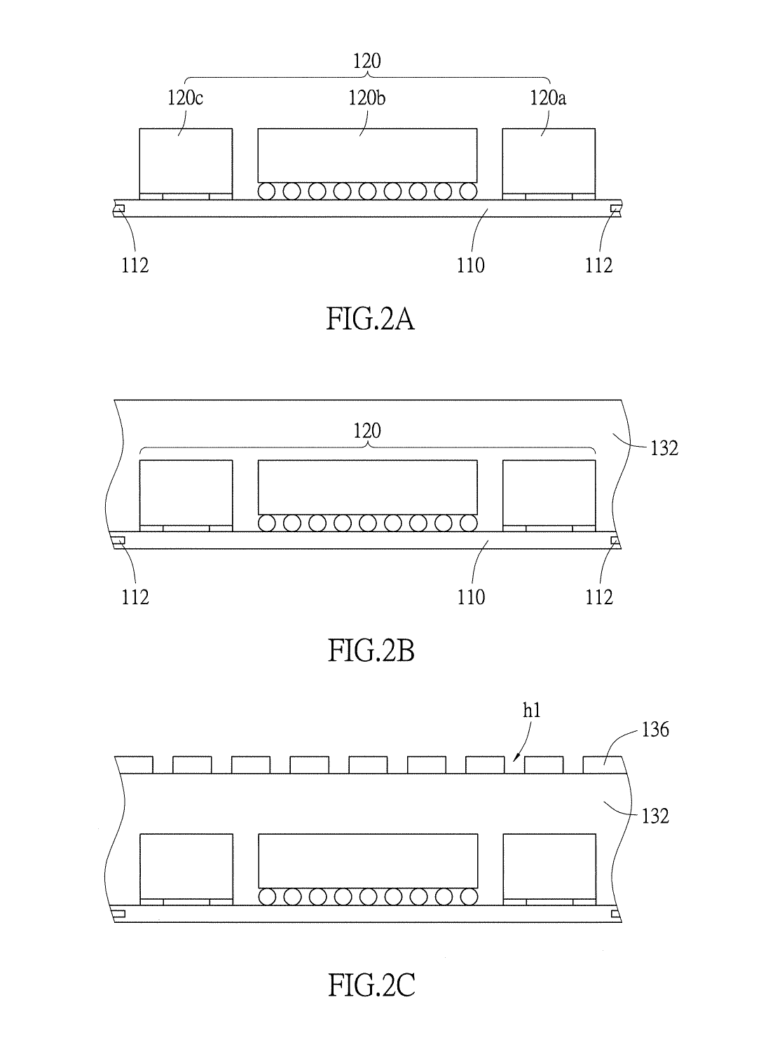

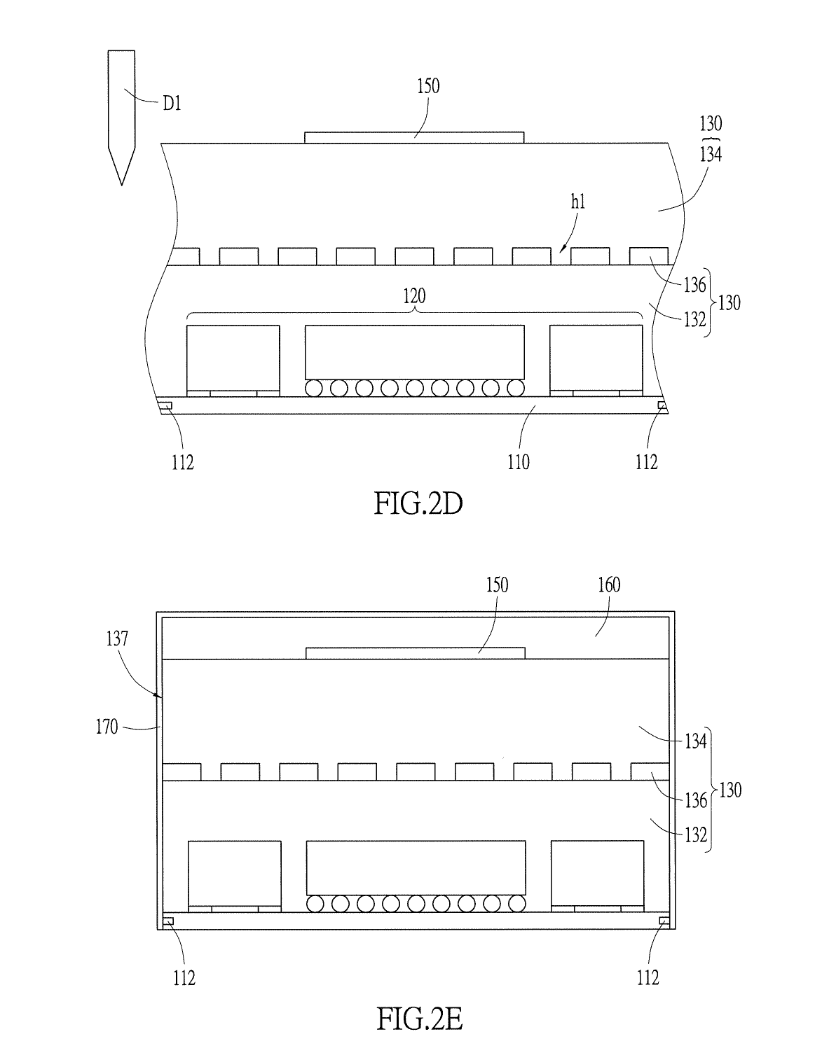

FIGS. 2A to 2D illustrate a semi-finished article diagram of a stacked package device in each step in accordance with an exemplary embodiment of the present disclosure. Please refer to FIGS. 2A to 2D seriatim.

First, please refer to FIG. 2A. The substrate 110 is provided. The substrate 110 may be a circuit substrate panel or a circuit substrate strip. FIG. 2A depicts merely part of the substrate 110. At least one electronic component 120 is disposed on the substrate 110. In the instant embodiment, the electronic components 120a, 120b, 120c are provided, which may be active components, passive components, chips or discrete components. The electronic component 120 is electrically connected to the substrate 110 by various ways. For example, the electronic component 120 may be electrically connected to the pads and traces of the substrate 110 by wire bonding flip chip bonding or other package methods.

Please refer to FIG. 2B. The first insulation layer 132 is formed on the substrate 110, and the first insulation layer 132 covers the electronic component 120.

Please refer to FIG. 2C. A metal layer is formed on the first insulation layer 132. The metal layer may be formed by using spray coating, ion plating, sputter deposition or evaporation.

Then, the metal layer is patterned to form the first shielding layer 136 which has a plurality of holes. Explicitly, the metal layer may be ablated by using laser to form the holes h1 on the metal layer so that the first shielding layer is formed. A portion of the first insulation layer 132 may be exposed through the holes h1. The diameter of the holes h1 is smaller than 25 μm. In other embodiment, the shape, number and location of the holes h1 would be depending upon: an antenna design, an electromagnetic requirement or processing requirement.

Please refer to FIG. 2D. The second insulation layer 134 is formed on the first shielding layer 136. In the process of fabricating the second insulation layer 134, before solidifying, the second insulation layer 134 may flow and contact the first insulation layer 132 via the holes h1. Upon contacting, the first and second insulation layers 132, 134 are tightly bonded. The first insulation layer 132, the second insulation layer 134, and the first shielding layer 136 collectively form the molding unit 130.

Then, an antenna 150 is formed on the second insulation layer 134. In the instant embodiment, the antenna 150 may be formed by attaching or spraying. Alternatively, after depositing metal layer on the upper surface of the second insulation layer 134, an etching can be conducted to form the antenna 150. In respect of practical application, the antenna 150 can be omitted in the present invention.

Then, as FIG. 2D shown, the molding unit 130 and the substrate 110 is cut into a plurality of units by using knife D1 or laser. It may not cut through the molding unit 130 and the substrate 110, namely half-cutting. The substrate 110 will be thoroughly cut at the last step.

Please refer to FIG. 2E. In order to form the second shielding layer 140 on the lateral side of the molding unit 130, the protecting layer 160 is formed on the upper surface of the second insulation layer 134 and covered the antenna 150. The protecting layer 160 may be ink coating which is used to be a mask during forming the second shielding layer 140. Next, a conductive material 170 is formed to conformally cover the sidewalls 137 and the protecting layer 160.

Please refer to FIG. 1B again. The protecting layer 160 is removed. Then, the second shielding layer 140 is completed. The second shielding layer 140 is electrically connected to the first shielding layer 136 and the grounding pad 112 to transmit the electromagnetic interference (EMI) or the radio frequency interference (RFI) to the grounding pad 112. In the instant embodiment, the material of the second shielding layer 140 is metal.

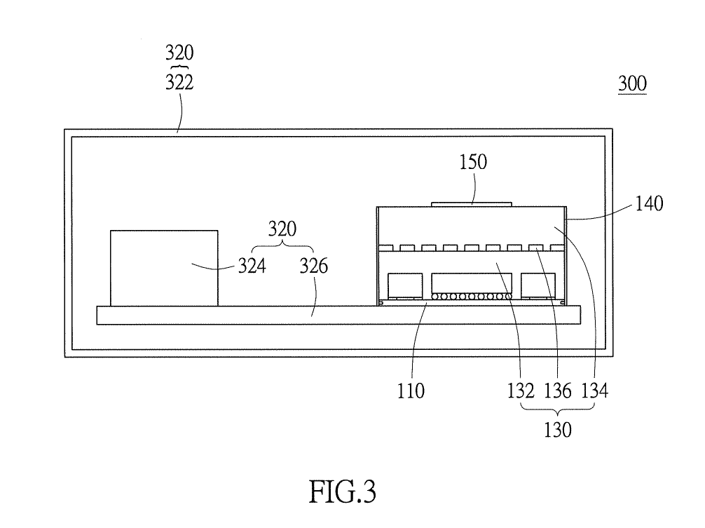

FIG. 3 illustrates a schematic diagram of an electronic device in accordance with an exemplary embodiment of the present disclosure. The electronic device 300 may be a communication system or a computer peripheral equipment, such as a cell phone, a tablet, a bluetooth receiver, a wireless base station, a router, etc.

The electronic device 300 includes the stacked package device 100 and a console 320. The stacked package device 100 is electrically connected to the console 320. The stacked package device 100 may be a data storage device or a wireless module. The stacked package device 100 includes the substrate 110, the electronic component 120, and the molding unit 130.

The console 320 includes a case 322, at least one electronic module 324 and a circuit board 326. In the instant embodiment, the stacked package device 100 and the electronic module 324 are disposed on the circuit board 326. The stacked package device 100, the electronic module 324, and the circuit board 326 are disposed in the case 322. In respect of practical application, the electronic module 324 may be an arithmetic processor, such as central processing unit (CPU), and the circuit board 326 may be a mainboard. The electronic module 324 is electrically connected to the stacked package device 100 through the circuit board 326, so that the electronic module 324 may control the operation of the stacked package device 100. In other embodiment, the electronic module 324 may be the stacked package device 100, the circuit board 326 may be the same material as substrate 110. Hence, the electronic device 300 includes more than one stacked package device 100.

In summary, in the present disclosure, the stacked package device includes the first shielding layer, the first shielding layer may increase the electromagnetic interference shielding effectiveness. A portion of the first insulation layer may be exposed through the holes. The first insulation layer material and the second insulation layer material may be the same, so that the first insulation layer and the second insulation layer may form a homogeneous connection with each another through the holes. Hence, the first insulation layer and the second insulation layer may closely combine with each other. Therefore, the delamination between the first insulation layer, the second insulation layer, and the first shielding layer may be avoided.

Additionally, in the present disclosure, the method of manufacturing the stacked package device includes using laser to form the holes on the metal layer so that the first shielding layer is formed. Hence, the first insulation layer and the second insulation layer may closely combine with each other, and the bonding strength of the molding compound between different layers is enhanced. Therefore, the delamination between the first insulation layer 132, the second insulation layer 134, and the first shielding layer 136 may be avoided.

The above-mentioned descriptions represent merely the exemplary embodiment of the present disclosure, without any intention to limit the scope of the present disclosure thereto. Various equivalent changes, alternations or modifications based on the claims of present disclosure are all consequently viewed as being embraced by the scope of the present disclosure.

What is claimed is:

1. A stacked package device comprising:
a substrate;
at least one electronic component disposed on the substrate; and
a molding unit including a first insulation layer, a second insulation layer, and a first shielding layer, the first shielding layer disposed between the first insulation layer and the second insulation layer, wherein the first shielding layer has a plurality of holes allowing material bonding between the first and second insulation layers.

2. The stacked package device according to claim 1 further comprising a second shielding layer, wherein the second shielding layer is disposed on portion of exterior of the molding unit, and the first shielding layer and the second shielding layer collectively form an electromagnetic interference shielding layer.

3. The stacked package device according to claim 1, wherein the diameter of the holes is smaller than 25 μm.

4. The stacked package device according to claim 1, wherein an upper surface of the first insulation layer is flat, and the first shielding layer covers the upper surface of the first insulation layer.

5. The stacked package device according to claim 1, wherein the first insulation layer material and the second insulation layer material are the same.

6. The stacked package device according to claim 1 further comprising an antenna formed on the second insulation layer.

7. A method of manufacturing the stacked package device comprising:
disposing at least one electronic component on a substrate, the electronic component electrically connected to the substrate;
forming a first insulation layer on the substrate, the first insulation layer covering the electronic component;
forming a metal layer on the first insulation layer;
patterning the metal layer with a plurality of holes to form a first shielding layer; and
forming a second insulation layer on the first insulation layer, wherein a portion of the second insulation layer flows through the holes and bonds with the first insulation layer before curing.

8. The method of manufacturing the stacked package device according to claim 7, wherein in the step of patterning the metal layer comprising:
ablating the metal layer by laser to form the holes.

9. The method of manufacturing the stacked package device according to claim 7, wherein the shape, number and location of the holes are depending upon an antenna design, an electromagnetic requirement or processing requirement.

10. The method of manufacturing the stacked package device according to claim 7, wherein the molding unit has a plurality of sidewall and the method of manufacturing the stacked package device further comprising:
forming a second shielding layer covering at least one side wall, and the first shielding layer and the second shielding layer collectively form an electromagnetic interference shielding layer.

11. An electronic device comprising:
a console including a case, at least one electronic module and a circuit board, the at least one electronic module and the circuit board disposed in the case; and
a stacked package device including:
a substrate electrically connected to circuit board;
at least one electronic component disposed on the substrate; and
a molding unit including a first insulation layer, a second insulation layer, and a first shielding layer, the first shielding layer disposed between the first insulation layer and the second insulation layer, wherein the first shielding layer has a plurality of holes allowing material bonding between the first and second insulation layers.

12. The electronic device according to claim 11 further comprising a second shielding layer, wherein the second shielding layer is disposed on portion of exterior of the molding unit, and the first shielding layer and the second shielding layer collectively form an electromagnetic interference shielding layer.

13. The electronic device according to claim 11, wherein the diameter of the holes is smaller than 25 μm.

14. The electronic device according to claim 11 further comprising an antenna formed on the second insulation layer.

15. The electronic device according to claim 11, wherein the first insulation layer is covered on at least on electronic component and part of the substrate.

16. The stacked package device according to claim 11, wherein the first insulation layer material and the second insulation layer material are the same.
